(19) United States
(12) Patent Application Publication
(10) Pub. No.: US 2019/0292662 A1
(43) Pub. Date: Sep. 26, 2019

(54) FILM-FORMING METHOD AND FILM-FORMING APPARATUS

(71) Applicant: TOKYO ELECTRON LIMITED, Tokyo (JP)

(72) Inventors: Hideomi HANE, Nirasaki City (JP); Kentaro OSHIMO, Nirasaki City (JP); Shimon OTSUKI, Oshu City (JP); Jun OGAWA, Nirasaki City (JP); Noriaki FUKIAGE, Nirasaki City (JP); Hiroaki IKEGAWA, Nirasaki City (JP); Yasuo KOBAYASHI, Nirasaki City (JP); Takeshi OYAMA, Nirasaki City (JP)

(21) Appl. No.: 16/363,488

(22) Filed: Mar. 25, 2019

(30) Foreign Application Priority Data
Mar. 26, 2018 (JP) 2018-058911

(51) Int. Cl. C23C 16/455; C23C 16/34; C23C 16/44; C23C 16/50

(52) U.S. Cl. CPC C23C 16/45544; C23C 16/345; C23C 16/50; C23C 16/4412; C23C 16/45502

(57) ABSTRACT

A film-forming method includes: mounting a substrate on a mounting table in a vacuu container; adsorbing a raw material to the substrate by supplying raw material gas containing silicon into the vacuum container; nitriding the raw material by supplying nitriding gas to a plasma formation region inside the vacuum container and supplying plasmarized gas to the substrate; forming a silicon-containing nitride film on the substrate by alternately and repeatedly performing the adsorbing a raw material and the nitriding the raw material; setting stress of the silicon-containing nitride film before the adsorbing a raw material and nitriding the raw material; and adjusting a nitriding time having a length based on first correspondence relationship between the stress of the silicon-containing nitride film and parameter corresponding to the nitriding time in the plasma formation region, and the set stress of the silicon-containing nitride film.

### CROSS-REFERENCE TO RELATED APPLICATION

This application is based upon and claims the benefit of priority from Japanese Patent Application No. 2018-058911, filed on Mar. 26, 2018, the entire contents of which are incorporated herein by reference.

### TECHNICAL FIELD

The present disclosure relates to a technique for forming a silicon-containing nitride film on a substrate.

### BACKGROUND

In forming a semiconductor device, a silicon-containing nitride film such as a silicon nitride (SiN) film is often formed on a substrate such as a semiconductor wafer (hereinafter, referred to as a “wafer”) by atomic layer deposition (ALD). In a film-forming apparatus that performs the ALD, there is a case where a wafer is mounted on a rotary table installed in a vacuum container, and the wafer that rotates by rotation of the rotary table repeatedly passes through an atmosphere to which a raw material gas is supplied and an atmosphere to which a reaction gas that reacts with the raw material gas is supplied so as to form a film.

An example of a specific process including the formation of an SiN film may include a process in which an SiN film is first formed on an underlying film, a pattern for etching the underlying film is formed on the SiN film, and then the underlying film is etched using the pattern as a mask. The pattern formed on the SiN film as such may have a relatively large height relative to its width. Since the pattern has such a shape, there is a possibility that the underlying film may not be etched due to its bending or collapsing in the case where the SiN film is not formed to have an appropriate film stress. Further, the aforementioned appropriate film stress may change under an influence of the stress of the underlying film. That is, in order to reliably etch the underling film, it is required that the stress of the SiN film formed in the ALD be adjusted.

In the related art, there is an apparatus which simultaneously supplies a silane gas, an ammonia gas and a hydrogen gas into a process container and plasmarizes these gases by a microwave to form an SiN film on a glass substrate by chemical vapor deposition (CVD). Although it is described that the stress of the SiN film is controlled and generation of pinholes in the SiN film is suppressed by controlling each of a power of the microwave and a flow rate of hydrogen, there is a desire for a technique capable of controlling the film stress to a desired value for the apparatus that performs the ALD.

### SUMMARY

Some embodiments of the present disclosure provide a technique capable of forming a silicon-containing nitride film so as to have a desired stress, in alternately supplying a raw material gas containing silicon and a nitriding gas for nitriding the raw material gas to a substrate to form the silicon-containing nitride film.

According to an embodiment of the present disclosure, there is provided a film-forming method, including: mounting a substrate on a mounting table installed in a vacuum container; adsorbing a raw material to the substrate by supplying a raw material gas containing silicon into the vacuum container; nitriding the raw material adsorbed to the substrate by supplying a nitriding gas to a plasma formation region inside the vacuum container so as to plasmarize a gas supplied to the plasma formation region and supply thus plasmarized gas to the substrate; forming a silicon-containing nitride film on the substrate by alternately and repeatedly performing the adsorbing a raw material and the nitriding the raw material; setting a stress of the silicon-containing nitride film before performing the adsorbing a raw material and nitriding the raw material; and adjusting a nitriding time during which nitriding the raw material is performed, the nitriding time having a length based on a first correspondence relationship between the stress of the silicon-containing nitride film and a parameter corresponding to the nitriding time in the plasma formation region, and the set stress of the silicon-containing nitride film.

According to an embodiment of the present disclosure, there is provided a film-forming apparatus, including: a vacuum container including therein a mounting table in which a substrate is mounted; a raw material gas supply part configured to supply a raw material gas containing silicon into the vacuum container to adsorb a raw material to the substrate; a plasma formation region located in the vacuum container so as to plasmarize a gas supplied to the plasma formation region and supply a plasmarized gas to the substrate; a nitriding gas supply part configured to supply a nitriding gas to the plasma formation region to generate a plasmarized nitriding gas and nitride the raw material adsorbed to the substrate, using the plasmarized nitriding gas; a controller configured to output a control signal such that a silicon-containing nitride film is formed by alternately and repeatedly supplying the raw material gas and supplying the plasmarized nitriding gas to the substrate; and a storage part configured to store a first correspondence relationship between a stress of the silicon-containing nitride film and a parameter corresponding to a nitriding time in the plasma formation region, wherein the controller is configured to output the control signal such that the plasmarized nitriding gas is supplied to the substrate during the nitriding time having a length that is based on a preset stress of the silicon-containing nitride film and the first correspondence relationship.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIGS. 1A to 1C illustrate a series of manufacturing processes of a semiconductor device including a film-forming process according to the present disclosure.

FIGS. 2A and 2B illustrate a series of manufacturing processes of a semiconductor device including the film-forming process according to the present disclosure.

FIG. 3 illustrates a longitudinal sectional view of a film-forming apparatus according to the present disclosure.

FIG. 4 illustrates a transverse plan view of the film-forming apparatus.

FIG. 5 illustrates a bottom view of a gas supply/exhaust unit installed in the film-forming apparatus.

FIG. 6 illustrates a longitudinal sectional view illustrating a modification region to which a hydrogen gas is supplied in the film-forming apparatus.

FIG. 7 illustrates a block diagram of a controller installed in the film-forming apparatus.

FIG. 8 illustrates a graph illustrating data stored in a memory of the controller.

FIG. 9 illustrates an explanatory view illustrating a gas supply state during the film-forming process.

FIG. 10 illustrates an explanatory view illustrating a gas supply state during the film-forming process.

FIG. 11 illustrates a longitudinal sectional side view illustrating another film-forming apparatus according to the present disclosure.

FIG. 12 illustrates a schematic view illustrating a longitudinal section of a wafer in an evaluation test.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

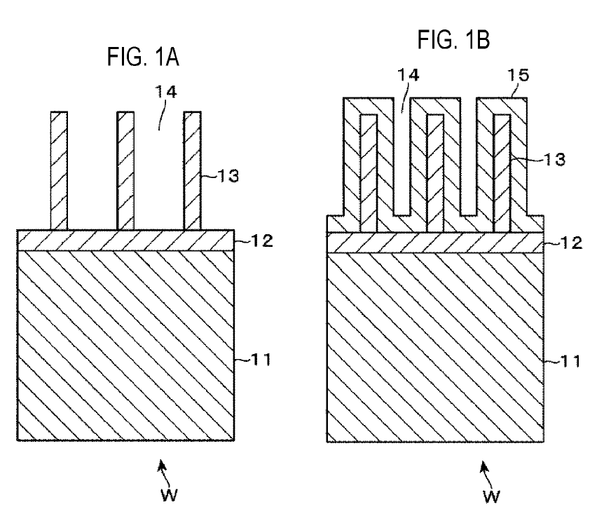

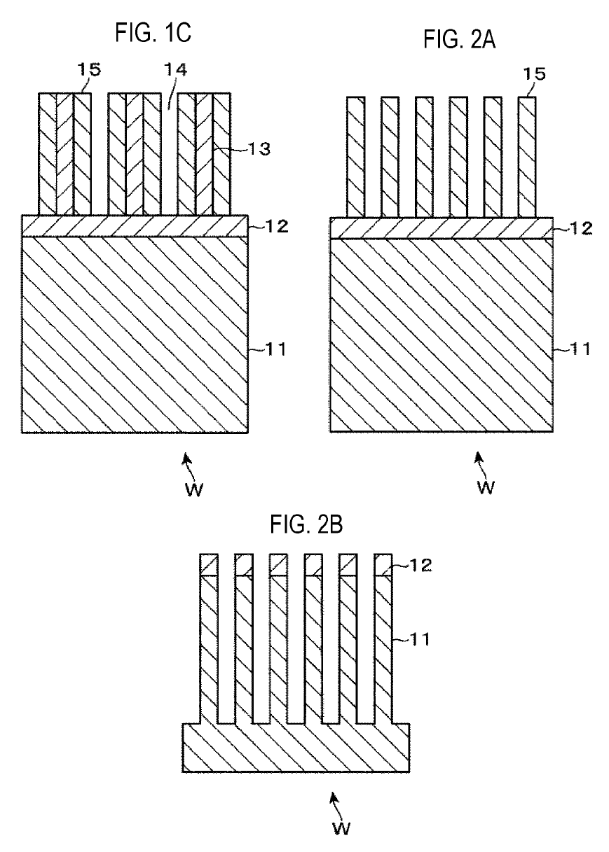

A series of processing steps on a wafer W including a film-forming process according to the present disclosure will be described with reference to FIGS. 1A to 1C, 2A and 2B. FIGS. 1A to 1C, 2A and 2B illustrate longitudinal sectional side views of a surface portion of the wafer W in these processing steps. First, referring to FIG. 1A, reference numeral 11 in the drawing denotes a silicon (Si) layer on which an underlayer film 12 is laminated. The underlayer film 12 is a film formed by laminating, for example, an SiN film and a silicon oxide (SiOx) film, and its upper end portion is formed by, for example, an SiOx film. Then, an amorphous Si film 13 is formed on the underlayer film 12. A groove 14 is formed in the amorphous Si film 13 so as to expose the underlayer film 12 such that the amorphous Si film 13 is formed to form a vertically elongated pattern.

An SiN film 15 as a thin film is formed so as to cover the amorphous Si film 13 and the underlayer film 12 along unevenness on the surface of the wafer W (FIG. 1B). Subsequently, etching is performed so that the upper end portion of the amorphous Si film 13 and the underlayer film 12 in the groove 14 are exposed (FIG. 1C). Thereafter, the amorphous Si film 13 is selectively etched, and a vertically elongated pattern of the SiN film 15, when viewed from a longitudinal section, is formed (FIG. 2A). Thereafter, the underlayer film 12 and the Si layer 11 are etched using the SiN film 15 as a mask to form a pattern on the Si layer 11 (FIG. 2B).

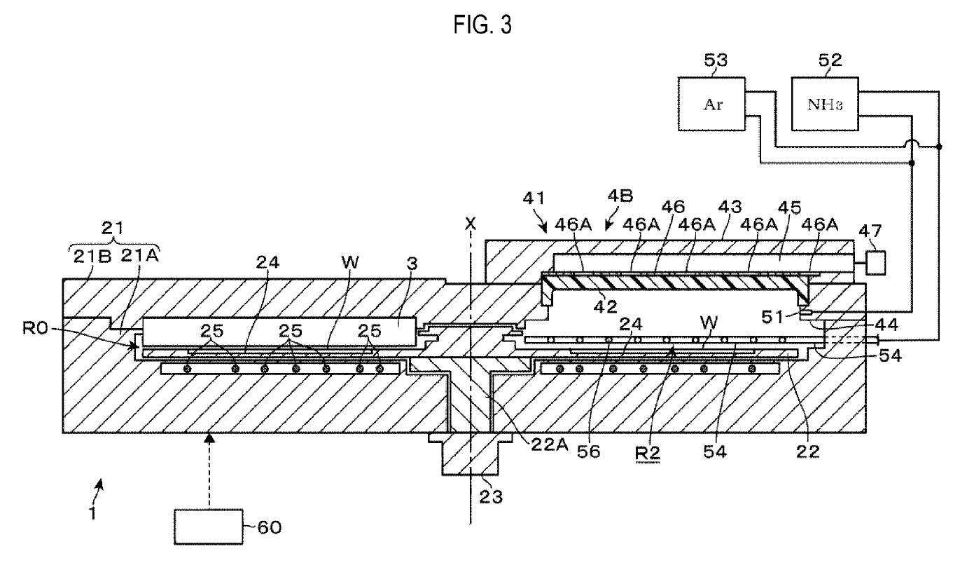

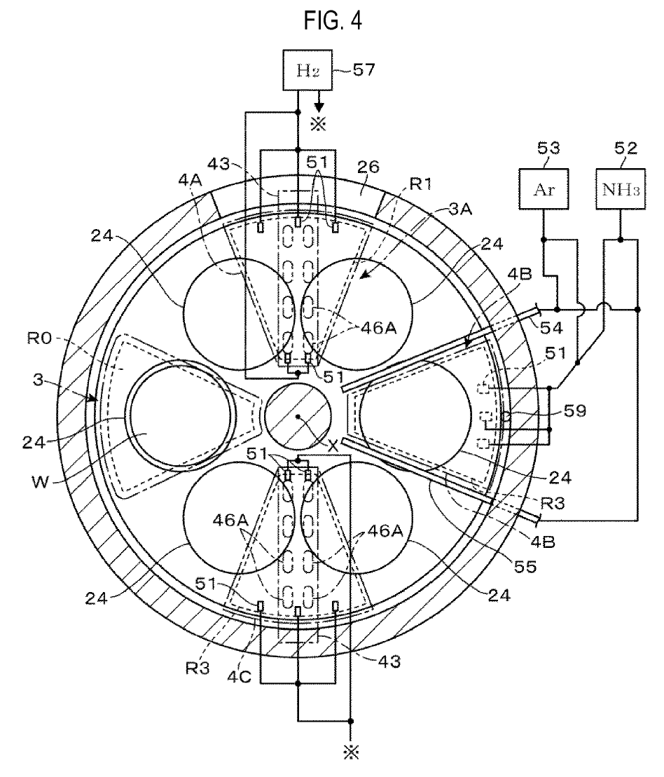

Subsequently, a film-forming apparatus 1 according to an embodiment of the present disclosure will be described with reference to a longitudinal sectional view of FIG. 3 and a transversal sectional plan view of FIG. 4. In this film-forming apparatus 1, the formation of the SiN film 15 described with reference to FIG. 1B, among the aforementioned processing steps, is performed by ALD. Furthermore, in the present disclosure, the silicon nitride film will be described as SiN regardless of stoichiometric ratio of Si and N. Accordingly, the description of SiN includes, for example, Si₃N₄. In addition, this film-forming apparatus 1 may be configured so that the stress of the SiN film 15 can be set by the user of the apparatus, and the SiN film may be formed so as to have a tensile stress or a compressive stress. Furthermore, the SiN film has a tensile stress when the value of the stress is positive, and a compressive stress when the value is negative.

In the drawing, reference numeral 21 denotes a flat, substantially circular vacuum container (process container), which is constituted by a container body 21A that forms a sidewall and a bottom portion, and a ceiling plate 21B. In the drawing, reference numeral 22 denotes a circular rotary table horizontally installed in the vacuum container 21. In the drawing, reference numeral 22A denotes a support part that supports a center of the rear surface of the rotary table 22. In the drawing, reference numeral 23 denotes a rotary mechanism which rotates the rotary table 22 clockwise in a circumferential direction, when viewed from the top side, through the support part 22A during the film-forming process. In the drawing, reference symbol X denotes a rotary shaft of the rotary table 22.

Six circular recesses 24 are provided on a top surface of the rotary table 22 along the circumferential direction (rotation direction) of the rotary table 22, and wafers W are stored in the respective recesses 24. That is, each wafer W is mounted on the rotary table 22 so as to be rotated by the rotation of the rotary table 22. In FIG. 3, reference numeral 25 denotes heaters, which are concentrically installed in a plural number at the bottom of the vacuum container 21 to heat the wafers W mounted on the rotary table 22. In FIG. 4, reference numeral 26 denotes a transfer port for the wafers W which is opened to the sidewall of the vacuum container 21, and which is configured to be opened and closed by a gate valve (not shown). The wafers W are transferred between the outside of the vacuum container 21 and the inside of the recesses 24 via the transfer port 26 by a substrate transfer mechanism (not shown).

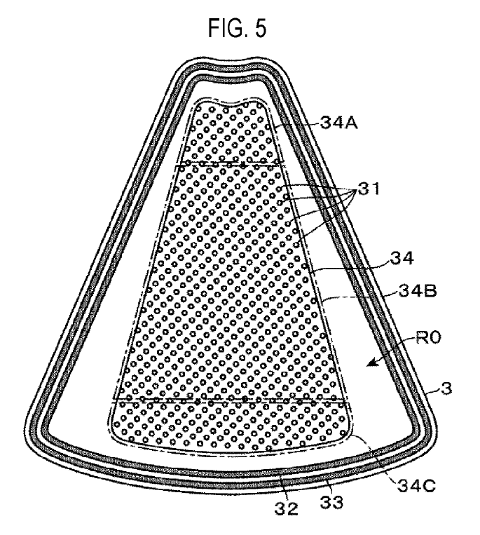

A gas supply/exhaust unit 3, a modification region R1, a reaction region R2, and a modification region R3 are sequentially installed on the rotary table 22 toward a downstream side in a rotation direction of the rotary table 22 along the rotation direction. Hereinafter, the gas supply/exhaust unit 3 will also be described with reference to FIG. 5 which is a bottom view. The gas supply/exhaust unit 3 constituting a raw material gas supply part is formed in a fan shape which widens in the circumferential direction of the rotary table 22 from the center side to the peripheral side of the rotary table 22 when viewed in a planar view, and a lower surface of the gas supply/exhaust unit 3 is close to and faces the top surface of the rotary table 22.

A gas discharge port 31, an exhaust port 32 and a purge gas discharge port 33 are opened on a lower surface of the gas supply/exhaust unit 3. In FIG. 5, in order to facilitate identification in the drawing, a plurality of dots are used to show the exhaust port 32 and the purge gas discharge port 33. A plurality of gas discharge ports 31 are arranged in a fan-shaped region 34 on the inner side of the peripheral edge of the lower surface of the gas supply/exhaust unit 3. The gas discharge ports 31 each discharge a DCS gas, which is a raw material gas containing Si (silicon) for forming an SiN film, in a shower shape downward during the rotation of the rotary table 22 during the film-forming process, and supplies it to the entire surface of the wafer W. Further, the raw material gas containing Si is not limited to DCS, and for example, hexachlorodisilane (HCD), tetrachlorosilane (TCS) or the like may be used.

In this fan-shaped region 34, three sections 34A, 34B, and 34C are set from the center side of the rotary table 22 toward the peripheral side of the rotary table 22. Gas passages (not shown), which are partitioned from each other, are provided in the gas supply/exhaust unit 3 so that the DCS gas can be supplied independently to the respective gas discharge ports 31 provided in the sections 34A, 34B and 34C. In addition, the upstream sides of these gas passages are connected to a gas supply source (not shown) that supplies the DCS gas to the respective gas passages. Furthermore, the gas supply source that supplies the DCS gas, and each gas supply source as described hereinbelow include a valve for controlling the supply and disconnection of the gas to the downstream side, a mass flow controller for adjusting the flow rate of the gas to the downstream side, and the like.

The exhaust port 32 and the purge gas discharge port 33 are annularly opened to the periphery of the lower surface of the gas supply/exhaust unit 3 so as to surround the fan-shaped region 34 and face the top surface of the rotary table 22, and the purge gas discharge port 33 is located outside the exhaust port 32. A region inside the exhaust port 32 on the rotary table 22 forms an adsorption region RO where the adsorption of DCS to the surface of the wafer W is performed. An exhaust device (not shown) is connected to the exhaust port 32, and a gas supply part that supplies an inert gas such as an argon (Ar) gas, as a purge gas, to the purge gas discharge port 33 is connected to the purge gas discharge port 33.

During the film-forming process, the discharge of the raw material gas from the gas discharge ports 31, the exhaust from the exhaust port 32, and the discharge of the purge gas from the purge gas discharge port 33 are all performed. Thus, the raw material gas and the purge gas discharged toward the rotary table 22 are exhausted from the exhaust port 32 with a top surface of the rotary table 22 facing the exhaust port 32. By performing the discharge and the exhaust of the purge gas in this way, the atmosphere of the adsorption region RO is separated from an external atmosphere such that the raw material gas can be limitedly supplied to an adsorption region RO. That is, since the DCS gas supplied to the adsorption region RO and a gas supplied to the outside of the adsorption region RO by plasma formation units 4A to 4C as described hereinbelow and active species of the gas can be suppressed from being mixed with each other, the film-forming process by ALD can be performed on the wafer W. Further, in addition to such a role of separating the atmosphere in this way, the purge gas also has a role of removing the DCS gas excessively adsorbed to the wafer W from the wafer W.

The plasma formation units 4A, 4B and 4C for forming plasma by activating the gases existing in the respective regions are installed in the modification region R1, the reaction region R2 and the modification region R3.

Hereinafter, the plasma formation unit 4B will be described. The plasma formation unit 4B supplies a gas onto the rotary table 22 and also supplies a microwave to the gas to generate plasma on the rotary table 22. The plasma formation unit 4B includes an antenna 41 for supplying the microwave, and the antenna 41 includes a dielectric plate 42 and a metallic waveguide 43.

The dielectric plate 42 has a substantially fan shape which widens from the center side toward the peripheral side of the rotary table 22 when seen in a planar view. A substantially fan-shaped through-hole is provided in the ceiling plate 21B of the vacuum container 21 so as to correspond to the shape of the dielectric plate 42. The inner peripheral surface of the lower end portion of the through-hole slightly protrudes to the center side of the through-hole to form the support part 44. The dielectric plate 42 closes the through-hole from above and is provided so as to face the rotary table 22, and the peripheral edge of the dielectric plate 42 is supported by the support part 44.

The waveguide 43 is installed on the dielectric plate 42 and has an internal space 45 extending along a radial direction of the rotary table 22. In the drawing, reference numeral 46 denotes a slot plate forming a lower portion of the waveguide 43. The slot plate is installed so as to make contact with the dielectric plate 42 and has a plurality of slot holes 46A. In FIG. 4, in the plasma formation unit 4B, the slot holes 46A are omitted. An end portion of the waveguide 43 on the center side of the rotary table 22 is closed, and a microwave generator 47 is connected to an end portion on the peripheral side of the rotary table 22. The microwave generator 47 supplies a microwave of, e.g., about 2.45 GHz, to the waveguide 43. The microwave supplied to the waveguide 43 passes through the slot holes 46A of the slot plate 46 and reaches the dielectric plate 42, and is supplied to the gas discharged below the dielectric plate 42 to plasmarize the gas. A lower portion side of the dielectric plate 42 on which the plasma is formed as described above forms the reaction region R2. Accordingly, the reaction region R2 is a substantially fan-shaped region that widens from the center side toward the peripheral side of the rotary table 22.

Further, the plasma formation unit 4B has gas discharge holes 51 in the support part 44 of the dielectric plate 42. A plurality of gas discharge holes 51 are located along the circumferential direction of the vacuum container 21, and the gas is discharged to the reaction region R2 from the peripheral side of the rotary table 22 toward the center side of the rotary table 22. In addition, the gas discharge holes 51 constituting a nitriding gas supply part are connected to an NH₃ gas supply source 52 for supplying an NH₃ gas and an Ar gas supply source 53 for supplying an Ar gas via a pipe system, and discharge these NH₃ gas and Ar gas. The NH₃ gas is a nitriding gas for nitriding the raw material gas, and the Ar gas is a gas for plasmarizing the NH₃ gas. That is, the plasma formation unit 4B is a unit which plasmarizes the NH₃ gas and performs a nitriding process in the reaction region R2.

Further, the NH₃ gas and the Ar gas are also supplied from gas injectors 54 and 55 installed near the reaction region R2 to the reaction region R2. The gas injectors 54 and 55 constituting the nitriding gas supply part are respectively installed on the upstream side of the rotary table 22 in the rotation direction and on the downstream side thereof in the rotation direction. Hereinafter, the rotation direction when it is described as the upstream side in the rotation direction and the downstream side in the rotation direction is assumed to be the rotation direction of the rotary table 22 unless specifically specified. These gas injectors 54 and 55 horizontally extend from the outside of the vacuum container 21 along the edge of the reaction region R2, and the leading end side thereof is located near the center portion of the rotary table 22 and is formed as a closed elongated tube. Furthermore, the base end portions of the gas injectors 54 and 55 are respectively connected to the NH₃ gas supply source 52 and the Ar gas supply source 53 via a pipe system. A plurality of discharge holes 56 are formed in the gas injectors 54 and 55 along the longitudinal direction of the gas injectors 54 and 55 so that the supplied NH₃ gas and Ar gas can be supplied to the reaction region R2.

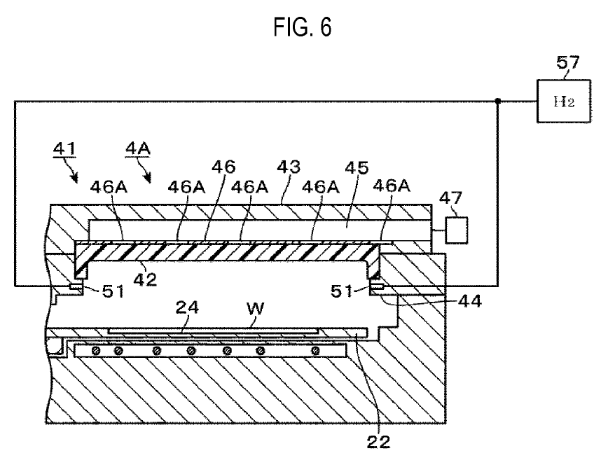

Subsequently, the plasma formation unit 4A and the plasma formation unit 4C will be described focusing on differences from the plasma formation unit 4B. The plasma formation units 4A and 4C are configured in the same manner, and the plasma formation unit 4A is illustrated as a representative in FIG. 6. In the plasma formation units 4A and 4C, the gas discharge holes 51 are located in the support part 44 so that the gas can be supplied from the peripheral side toward the center side of the rotary table 22 and from the center side toward the peripheral side of the rotary table 22. Each gas discharge hole 51 is connected to an H₂ gas supply source 57 for supplying a hydrogen (H₂) gas, and the H₂ gas is supplied from the gas discharge hole 51 to the modification regions R1 and R3. As the microwave is supplied to the H₂ gas, the H₂ gas is plasmarized. The plasmarized H₂ gas acts on chlorine in the SiN film 15 to remove it and modify the SiN film 15. Therefore, the gas discharge holes 51 of the plasma formation units 4A and 4B constitute a hydrogen gas supply part.

As described above, the modification regions R1 and R3 and the reaction region R2 already described above are formed as a plasma formation region, and are set apart from the adsorption region RO that is a supply region of the raw material gas in the rotation direction. Among these modification region R1, reaction region R2 and modification region R3, partition of the atmosphere by the purge gas, such as partition between the adsorption region R0 and its external region, is not performed.

Further, as illustrated in FIG. 4, for example, an exhaust port 59 is opened at the bottom of the vacuum container 21 outside the rotary table 22 in the reaction region R2. The exhaust port 59 is connected to an exhaust mechanism (not shown) such as a vacuum pump or the like so that the exhaust amount from the exhaust port 59 is adjustable.

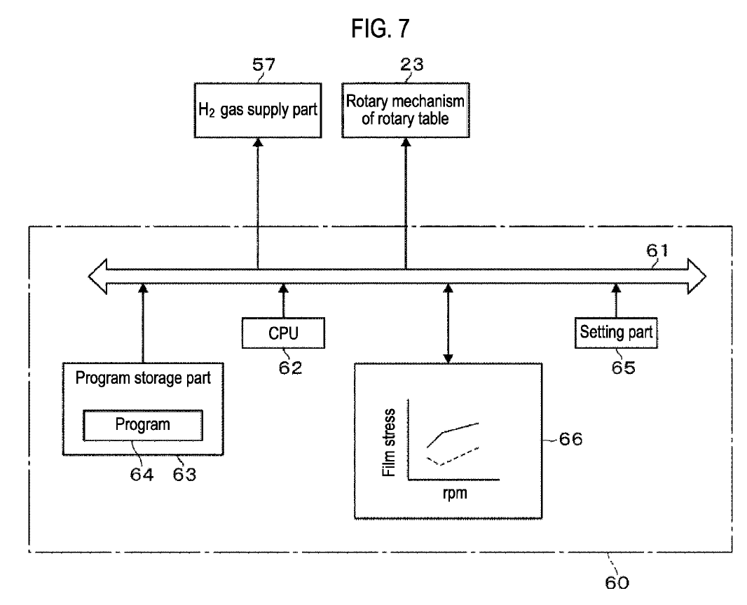

A controller 60 including a computer is installed in a film-forming apparatus 2. FIG. 7 illustrates a configuration of the controller 60 and reference numeral 61 denotes a bus. Reference numeral 62 denotes a CPU that performs various operations. Reference numeral 63 denotes a program storage part in which a program 64 is stored. Reference numeral 65 denotes a setting part for setting the stress of the SiN film 15 desired by the user of the apparatus, which is configured by, for example, a touch panel, a keyboard, or the like. Reference numeral 66 denotes a memory (memory part), which stores a correspondence relationship between the set stress of the SiN film 15 and processing parameters of the film-forming apparatus 1. When the stress of the SiN film 15 is set, the processing parameters corresponding to the stress are read from the correspondence relationship, and processing is performed based on the read process parameters.

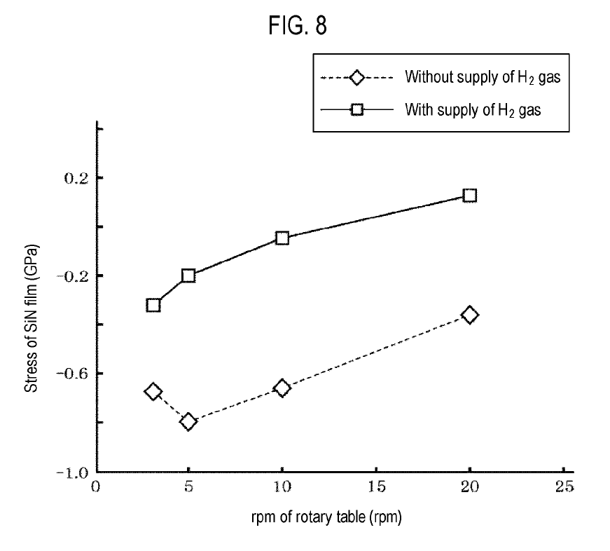

These processing parameters are revolutions per minute (rpm) of the rotary table 22 and a flow rate of the H₂ gas from the H₂ gas supply source 57 to the modification regions R1 and R3 during the film-forming process. In this example, since the flow rate of the H₂ gas is selectively determined from 0 and predetermined values other than 0, the flow rate of the H₂ gas as the processing parameters may more specifically refer to the presence or absence of supply of the H₂ gas from the H₂ gas supply source 57 to the regions R1 and R3. A graph illustrated in FIG. 8 indicates the data stored in the memory 66 and is acquired by performing an experiment. The revolutions per minute (unit: rpm) of the rotary table 22 is set on the horizontal axis and the stress (unit: GPa) of the SiN film 15 is set on the vertical axis. The relationship between the rpm of the rotary table 22 and the stress of the SiN film 15 is illustrated in each of the case where the H₂ gas is not supplied to the modification regions R1 and R3 and the case where the H₂ gas is supplied thereto.

In the case where the H₂ gas is supplied, the stress of the SiN film 15 increases as the rpm of the rotary table 22 increases in a range of 3 to 20 rpm. In the case where the H₂ gas is not supplied, the stress of the SiN film 15 decreases as the rpm of the rotary table 22 increases in a range of 3 to 5 rpm, and the stress of the SiN film 15 increases as the rpm of the rotary table 22 increases in a range of 5 to 20 rpm. In addition, when the rpm of the wafer W has an arbitrary value, the stress of the SiN film 15 becomes larger in the case where the H₂ gas is supplied than in the case where the H₂ gas is not supplied.

Further, according to this graph, it can be seen that the stress of the SiN film 15 can be changed within a range of −0.8 to 0.08 GPa by adjusting the rpm of the rotary table 22 within the range of 3 to 20 rpm and selecting the presence or absence of supply of the H₂ gas to the modification regions R1 and R3. That is, when forming the SiN film 15 having a desired stress within the range of −0.8 to 0.08 GPa, the rpm of the rotary table 22 and the presence or absence of supply of the H₂ gas from the H₂ gas supply source 57 to the modification regions R1 and R3 can be determined based on this graph. In addition, when the stress of the SiN film 15 is set, there is a case where two rpms of the rotary table 22 for obtaining the set stress can be set from this graph, but in this case, for example, it is determined in advance which one of the higher value and the lower value is to be set. Further, it is considered that the reason why the stress of the SiN film 15 is changed by changing the rpm of the rotary table 22 is that the nitriding time during which the nitriding process is performed during a time period in which the wafer W is exposed to the plasmarized NH₃ gas, i.e., in one cycle of ALD, is changed. In the film-forming apparatus 2, this nitriding time is adjusted by adjusting the rpm of the rotary table 22.

Subsequently, the program 64 will be described. Regarding the program 64, a group of steps are configured to cause the film-forming process as described later to be executed by transmitting a control signal to each part of the film-forming apparatus 2 to control its operation. Specifically, the rpm of the rotary table 22 by the rotary mechanism 23, the flow rates and the supply and disconnection of the respective gases by the respective gas supply parts, the exhaust amount by the exhaust port 59, the supply and disconnection of the microwave from the microwave generator 47 to the antenna 41, the power supply to the heater 25, and the like are controlled by the program 64. The control of the power supply to the heater 25 is the control of the temperature of the wafer W, and the control of the exhaust amount by the exhaust port 59 is, i.e., the control of the pressure of the interior of the vacuum container 21.

The control of the rpm of the rotary table 22 by the program 64 is performed based on the stress of the SiN film 15 set by the setting part 65 and the graph illustrated in FIG. 8. Similarly, the supply of the H₂ gas from the H₂ gas supply source 57 is also performed based on the stress of the SiN film 15 set by the setting part 65 and the graph illustrated in FIG. 8. The program 64 is stored in the program storage unit 62 in a state of being stored in a storage medium such as a hard disk, a compact disc, a magneto-optical disc, a memory card, or a DVD, and is installed in the controller 60.

Hereinafter, the film-forming process performed by the film-forming apparatus 2 will be described. First, when the user sets a desired value for the stress of the SiN film 15 from the setting part 65, the controller 60 determines the rpm of the rotary table 22 and the presence or absence of supply of the H₂ gas from the H₂ gas supply source 57 to the modification regions R1 and R3 based on the set value and the graph of FIG. 8. Here, description will be made assuming that it is determined that the supply of the H₂ gas to the modification regions R1 and R3 is performed.

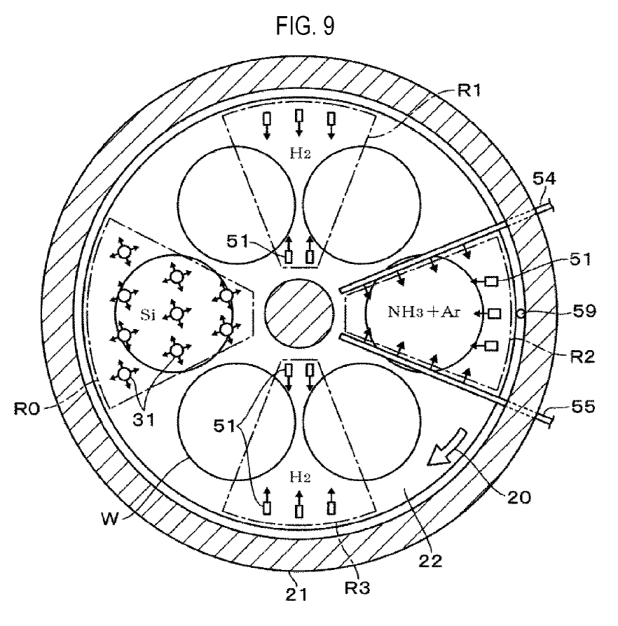

Subsequently, when six wafers W whose surfaces are formed as illustrated in FIG. 1A are transferred to the respective recesses 24 of the rotary table 22 by a substrate transfer mechanism (not shown), the gate valve in the transfer port 26 for the wafers W is closed and the interior of the vacuum container 21 is sealed airtight. The wafers W mounted in the recesses 24 are heated to a predetermined temperature by the heater 25. Then, the interior of the vacuum container 21 is brought into a vacuum atmosphere of a predetermined pressure by the exhaust from the exhaust port 59, and the rotary table 22 rotates at the determined rpm as already described above. Subsequently, a DCS gas is limitedly supplied to the adsorption region R0 on the rotary table 22 by supplying and exhausting each gas from the gas supply/exhaust unit 3. In addition, each gas is supplied from each gas discharge hole 51 of the plasma formation units 4A, 4B and 4C and the gas injectors 54 and 55, and a microwave is supplied to the modification regions R1 and R3 and the reaction region R2. Thus, plasma of the H₂ gas is formed in the modification regions R1 and R3, and plasma of the Ar gas and the NH₃ gas is formed in the reaction region R2. FIG. 9 illustrates a state when each gas is formed and a film is formed in this way. In the drawing, the arrow 20 indicates the rotation direction of the rotary table 22.

The wafers W are sequentially and repeatedly moved over to the adsorption region R0, the modification region R1, the reaction region R2, and the modification region R3 by the rotation of the rotary table 22, and the supply of the DCS gas, the supply of active species of the H₂ gas, the supply of active species of the NH₃ gas, and the supply of active species of the H₂ gas, when viewed from the wafers W, are sequentially repeated. As a result, an island-shaped SiN layer is grown on the surface of the wafers W so as to be modified and widened. Even thereafter, SiN is deposited on the surface of the wafer W by continuing the rotation of the rotary table 22, and a thin layer grows to become the SiN film 15 to increase the thickness of the SiN film 15. Then, as illustrated in FIG. 1B, when the SiN film 15 having a desired film thickness is formed the discharge and exhaust of each gas in the gas supply/exhaust unit 3 are stopped, the supply of each gas from the gas discharge holes 51 and the gas injectors 54 and 55 and the supply of microwave to the modification regions R1 and R3 and the reaction region R2 are stopped, and the film-forming process is completed. After the film-forming process, the wafers W are unloaded from the film-forming apparatus 1 by the substrate transfer mechanism.

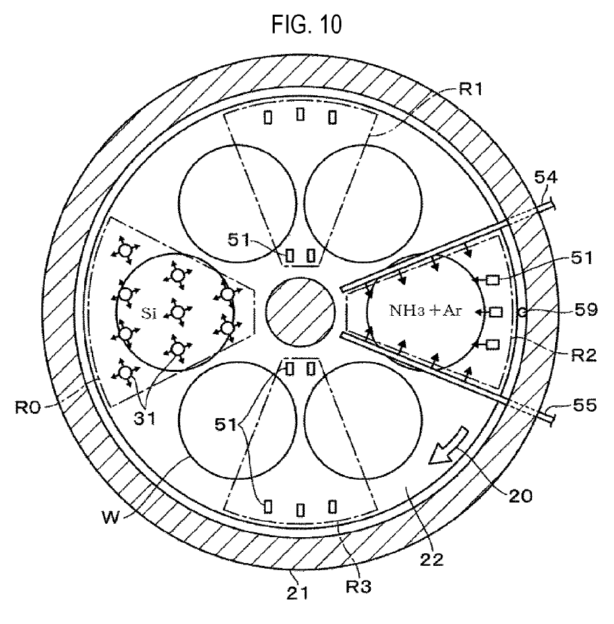

The film-forming process in the case where it is determined that the supply of the H₂ gas from the H₂ gas supply source 57 to the modification regions R1 and R3 is not performed as a result of setting the desired value for the stress of the SiN film 15 from the setting part 65 by the user will also be described. In this case, except that the supply of the H₂ gas is not performed as such, the film-forming process is performed in the same manner as in the case where it is determined that the supply of the H₂ gas is performed. FIG. 10 illustrates a state when the film-forming process is performed without supplying the H₂ gas as such. Even when the H₂ gas is not supplied as such, the microwave is supplied to the modification regions R1 and R3. Further, it is considered that the H₂ gas existing in trace amounts in the modification regions R1 and R3 is plasmarized, and when the wafer W passes through the modification regions R1 and R3, the modification is performed.

According to this film-forming apparatus 1, the rpm of the rotary table 22 and the presence or absence of supply of the H₂ gas to the modification regions R1 and R3 are determined according to the set stress, and the SiN film 15 can be formed so as to have the set stress. Therefore, when the SiN film 15 is formed in a vertically elongated pattern as illustrated in FIG. 2A, it is possible to suppress it from being bent and collapsed. As a result, it is possible to prevent the etching process of the Si layer 11 using the SiN film 15 as illustrated in FIG. 2B as a mask from becoming abnormal, and to suppress a reduction in the yield of a semiconductor device manufactured from the wafers W.

Meanwhile, assuming that the correspondence relationship between the stress of the SiN film 15 and the rpm of the rotary table 22 is a first correspondence relationship, both the first correspondence relationship when the H₂ gas is supplied as indicated by a solid line graph in FIG. 8 and the first correspondence relationship when the H₂ is not supplied as indicated by a dotted line graph in FIG. 8 are stored in the memory 66. However, the first correspondence relationship of only one of these may be stored. That is, whether or not the H₂ gas is supplied to the modification regions R1 and R3 during the film-forming process may be determined in advance regardless of the setting of the stress of the SiN film 15 by the user, such that only the rpm of the rotary table 22 is determined according to the setting of the stress of the SiN film 15. However, in some embodiments, an apparatus configuration may be adopted in which both the rpm and the presence or absence of supply of the H₂ gas are determined, whereby the settable range of the stress of the SiN film 15 can be increased, and the SiN film 15 can have the tensile stress or the compressive stress as described above.

Further, the film-forming apparatus 1 may be configured so as to perform the film-forming process at a predetermined rpm regardless of the setting of the stress of the SiN film 15 by the user such that only the presence or absence of supply of the H₂ gas by setting the stress of the film by the user is determined. For example, it is assumed that the rotary table 22 is determined to rotate at 20 rpm during the film-forming process. Further, the stress of the SiN film is stored in the memory 66 for both when the H₂ gas is supplied and when the H₂ gas is not supplied in the case where it is rotated at 20 rpm as such. The presence or absence of supply of the H₂ gas may be determined so that the stress becomes a value close to the stress set by the user using the setting part 65. That is, assuming that the correspondence relationship between the presence or absence of supply of the H₂ gas and the stress of the SiN film to be formed is a second correspondence relationship, both the first correspondence relationship and the second correspondence relationship are included in the memory 66 in the configuration example described with reference to FIG. 7 or the like, but only the second correspondence relationship may be included therein.

Further, in the configuration example of the aforementioned apparatus, it is illustrated that the data of the graph of FIG. 8 is included in the memory 66, but it is not limited to such a configuration. For example, from the graph of FIG. 8 indicated at a place different from that of the film-forming apparatus 1, the user may read and set the rpm of the rotary table 22 and the presence or absence of supply of the H₂ gas such that the stress of the SiN film 15 becomes a desired value. Moreover, in the process example described above, regarding the flow rate of the H₂ gas supplied to the modification regions R1 and R3, a first flow rate and a second flow rate larger than the first flow rate are switched so as to obtain a desired film stress, and the first flow rate is set to zero. However, the first flow rate is not limited to zero as such, but may be any amount other than zero.

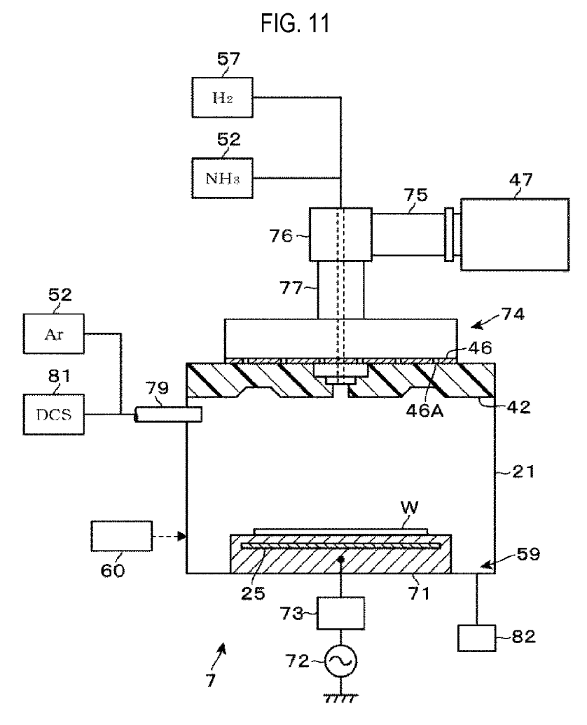

Further, the film-forming apparatus of the present disclosure is not limited to being configured as a batch-type film-forming apparatus such as the film-forming apparatus 2 which stores a plurality of wafers W in the vacuum container 21 and processes them in batch, but it may be configured as a single-wafer-type film-forming apparatus 7 which stores and processes only one wafer W in the vacuum container 21 as illustrated in FIG. 11. The film-forming apparatus 7 will be described focusing on differences from the film-forming apparatus 2. Further, in this film-forming apparatus 7, the components having the same functions as those of the aforementioned film-forming apparatus 2 are denoted by the same reference numerals as those used in the film-forming apparatus 2.

A mounting table 71 on which a wafer W is mounted is installed in a vacuum container 21 of the film-forming apparatus 7, and a high-frequency power supply 72 for applying a high-frequency bias power (e.g., 13.56 MHz) is connected to the mounting table 71 via a matching unit 73. A heater 25 is installed in the mounting table 71 to heat the wafer W mounted on the mounting table 71. A ceiling part of the vacuum container 21 is configured as a microwave supply part 74. A microwave of TE mode of, e.g., 2.45 GHz, generated by a microwave generator 47 is supplied to a mode converter 76 via a waveguide 75 to convert it into a TEM mode and then supplied into the vacuum container 21 via a coaxial waveguide 77, a slot plate 46 having a slot hole 46A formed therein, and a dielectric plate 42 forming the ceiling surface of the vacuum container 21. Thus, each gas supplied into the vacuum container 21 can be plasmarized.

For example, an NH₃ gas and an H₂ gas are introduced into the vacuum container 21 using the mode converter 76 and a gas supply line 78 formed in the coaxial waveguide 77. Further, for example, a DCS gas and an Ar gas are supplied into the vacuum container 21 via the gas supply pipe 79. This Ar gas is also used as a purge gas for purging the interior of the vacuum container 21, in addition to plasmarizing the NH₃ gas. In the drawing, reference numeral 81 denotes a DCS gas supply part, and in the drawing, reference numeral 82 denotes an exhaust mechanism connected to an exhaust port 59.

A correspondence relationship between the stress of the SiN film 15 and the nitriding time in one cycle of ALD is stored in a memory 66 of a controller 60 provided in the film-forming apparatus 7 is stored for each of the case where the H₂ gas is supplied into the vacuum container 21 and the case where the H₂ gas is not supplied into the vacuum container 21. The nitriding time in one cycle of the ALD may indicate the time required for the wafer W to pass through the reaction region R2 in the film-forming apparatus 2, and thus can be calculated by multiplying the rpm of the rotary table 22 by a predetermined coefficient. That is, the data corresponding to the memory 66 of the film-forming apparatus 2 is stored in the memory 66 of the film-forming apparatus 7.

When performing the film-forming process in the film-forming apparatus 7, the stress of the SiN film 15 is input by the user in the same manner as in the case where the film-forming process is performed by the film-forming apparatus 2, and the presence or absence of supply the H₂ gas, and the nitriding time described above are determined based on the already described data stored in the memory 66. When it is determined that the supply of the H₂ gas is performed, a cycle which performs the supply of the DCS gas, the supply of the purge gas (Ar gas), the supply of the H₂ gas, the supply of the purge gas, the supply of the NH₃ gas and the supply of the Ar gas, the supply of the purge gas, the supply of the H₂ gas, and the supply of the purge gas into the vacuum container 21 is repeatedly implemented to thus form an SiN film 15 having a desired film thickness. When the H₂ gas is supplied and when the NH₃ gas and the Ar gas are supplied, the microwave is supplied into the vacuum container 21 to plasmarize the aforementioned gases.

On the other hand, when it is determined that the H₂ gas is not supplied, a cycle which performs the supply of the DCS gas, the supply of the purge gas (Ar gas), the supply of the NH₃ gas, the supply of the Ar gas, and the supply of the purge gas into the vacuum container 21 is repeatedly implemented to thus form an SiN film 15 having a desired film thickness. When the NH₃ gas and the Ar gas are supplied, the microwave is supplied into the vacuum container 21 to plasmarize these gases. In both when it is determined that the H₂ gas is supplied and when it is determined that the H₂ gas is not supplied, the time at which the NH₃ gas and the Ar gas are supplied, i.e., the aforementioned nitriding time, is controlled to be equal to the time determined as described above.

However, the present disclosure is not limited to the aforementioned embodiments, and the aforementioned embodiments may be appropriately combined or modified. For example, in the film-forming apparatus 2, the reaction region R2, and the modification regions R1 and R3 are not limited to the examples described above, but the modification regions R1 and R3 and the reaction region R2 may be sequentially arranged in the clockwise direction. Furthermore, the method of plasmarizing the H₂ gas or the NH₃ gas in the film-forming apparatus 2 described above is not limited to the example using the microwave, but inductively coupled plasma (ICP) may be generated using an antenna. In addition, a silicon-containing nitride film formed by the film-forming apparatus 2 is not limited to the SiN film, but may be, for example, a carbon-containing silicon nitride film (SiCN film) or the like. In order to form the SiCN film, for example, a nozzle for supplying a gas containing carbon such as methane or the like is installed in the reaction region R2, and the carbon-containing gas may be supplied together with the NH₃ gas and the Ar gas to the reaction region R2 to plasmarize these gases in the region R2.

### (Evaluation Tests)

Next, evaluation tests conducted in connection with the present disclosure will be described.

### (Evaluation Test 1)

The series of processes described with reference to FIGS. 1A to 2A were performed on a plurality of wafers W to form a pattern in the SiN film 15. For the SiN film 15, the film was formed so as to have a different stress for each wafer W using the film-forming apparatus 2, and specifically, the film was formed so that the stress becomes +50 MPa and −200 MPa. Then, the wafer W after forming the pattern of the SiN film 15 was cleaned using diluted hydrofluoric acid (DHF), and the longitudinal cross section of each wafer W was imaged using a transmission electron microscope (TEM).

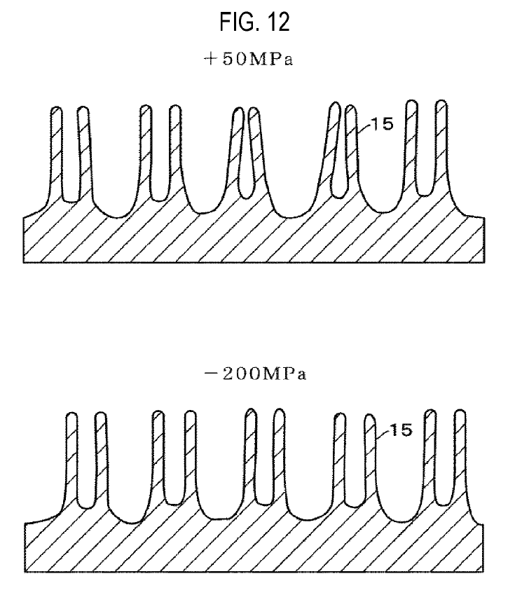

A schematic view of FIG. 12 illustrates a longitudinal cross section of the wafer W imaged as described above, in which the upper stage shows a longitudinal sectional view when the stress of the SiN film 15 is +50 MPa and the lower stage shows a longitudinal sectional view when the stress of the SiN film 15 is −200 MPa. As it will become apparent from FIG. 12, the pattern of the SiN film 15 having the stress of +50 MPa has inclined and collapsed. However, in the pattern of the SiN film 15 having the stress of −200 MPa, such inclination and collapse did not occur. Therefore, it is presumed that it is possible to suppress the inclination and collapse of the pattern by making the stress of the SiN film 15 appropriate.

According to the present disclosure in some embodiments, a nitriding time is adjusted based on a first correspondence relationship between a stress of a silicon-containing nitride film and parameters corresponding to the nitriding time in a plasma formation region or a hydrogen gas is supplied based on a second correspondence relationship between the stress of the silicon-containing nitride film and a flow rate of a hydrogen gas supplied to the plasma formation region, in alternately and repeatedly supplying a raw material gas containing silicon and a plasmarized nitriding gas to a substrate to form a silicon-containing nitride film. Thus, it is possible to form the stress of the silicon-containing nitride film so as to have a desired stress.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A film-forming method, comprising:
mounting a substrate on a mounting table installed in a vacuum container;
adsorbing a raw material to the substrate by supplying a raw material gas containing silicon into the vacuum container;
nitriding the raw material adsorbed to the substrate by supplying a nitriding gas to a plasma formation region inside the vacuum container so as to plasmarize a gas supplied to the plasma formation region and supply thus plasmarized gas to the substrate;
forming a silicon-containing nitride film on the substrate by alternately and repeatedly performing the adsorbing a raw material and the nitriding the raw material;
setting a stress of the silicon-containing nitride film before performing the adsorbing a raw material and the nitriding the raw material; and
adjusting a nitriding time during which nitriding the raw material is performed, the nitriding time having a length based on a first correspondence relationship between the stress of the silicon-containing nitride film and a parameter corresponding to the nitriding time in the plasma formation region, and the set stress of the silicon-containing nitride film.

2. A film-forming method, comprising,:
mounting a substrate on a mounting table installed in a vacuum container;
adsorbing a raw material to the substrate by supplying a raw material gas containing silicon into the vacuum container;
nitriding the raw material adsorbed to the substrate by supplying a nitriding gas to a plasma formation region inside the vacuum container so as to plasmarize a gas supplied to the plasma formation region and supply thus plasmarized gas to the substrate;
forming a silicon-containing nitride film on the substrate by alternately and repeatedly performing the adsorbing a raw material and the nitriding the raw material;
setting a stress of the silicon-containing nitride film before performing the adsorbing a raw material and the nitriding the raw material; and
adjusting a hydrogen gas flow rate by supplying a hydrogen gas to the plasma formation region at a flow rate that is based on a second correspondence relationship between the stress of the silicon-containing nitride film and the flow rate of the hydrogen gas supplied to the plasma formation region, and the set stress of the silicon-containing nitride film.

3. The method of claim 1, further comprising:
adjusting a hydrogen gas flow rate by supplying a hydrogen gas to the plasma formation region at a flow rate that is based on a second correspondence relationship between the stress of the silicon-containing nitride film and the flow rate of the hydrogen gas supplied to the plasma formation region, and the set stress of the silicon-containing nitride film.

4. The method of claim 2, further comprising:
adjusting a nitriding time during which the nitriding the raw material is performed, the nitriding time having a length based on a first correspondence relationship between the stress of the silicon-containing nitride film and a parameter corresponding to the nitriding time in the plasma formation region, and the set stress of the silicon-containing nitride film.

5. The method of claim 2, wherein the second correspondence relationship is set so that the flow rate of the hydrogen gas supplied to the plasma formation region is zero or selected among flow rates other than zero.

6. The method of claim 3, wherein the second correspondence relationship is set so that the flow rate of the hydrogen gas supplied to the plasma formation region is zero or selected among flow rates other than zero.

7. The method of claim 4, wherein the second correspondence relationship is set so that the flow rate of the hydrogen gas supplied to the plasma formation region is zero or selected among flow rates other than zero.

8. The method of claim 5, further comprising:
rotating the substrate by rotating a rotary table which acts as the mounting table,
wherein the adsorbing a raw material includes passing the substrate that rotates with respect to a raw material gas supply region separated from the plasma formation region in a rotational direction of the rotary table,
wherein the nitriding the raw material includes passing the substrate that rotates with respect to the plasma formation region, and
wherein a parameter corresponding to a nitriding time in the plasma formation region is revolutions per minute (rpm) of the rotary table.

9. The method of claim 6, further comprising:
rotating the substrate by rotating a rotary table which acts as the mounting table,
wherein the adsorbing a raw material includes passing the substrate that rotates with respect to a raw material gas supply region separated from the plasma formation region in a rotational direction of the rotary table,
wherein the nitriding the raw material includes passing the substrate that rotates with respect to the plasma formation region, and
wherein the parameter corresponding to the nitriding time in the plasma formation region is revolutions per minute (rpm) of the rotary table.

10. The method of claim 7, further comprising:
rotating the substrate by rotating a rotary table which acts as the mounting table,
wherein the adsorbing a raw material includes passing the substrate that rotates with respect to a raw material gas supply region separated from the plasma formation region in a rotational direction of the rotary table,
wherein the nitriding the raw material includes passing the substrate that rotates with respect to the plasma formation region, and
wherein the parameter corresponding to the nitriding time in the plasma formation region is revolutions per minute (rpm) of the rotary table.

11. A film-forming apparatus, comprising:
a vacuum container including therein a mounting table in which a substrate is mounted;
a raw material gas supply part configured to supply a raw material gas containing silicon into the vacuum container to adsorb a raw material to the substrate;
a plasma formation region located in the vacuum container so as to plasmarize a gas supplied to the plasma formation region and supply a plasmarized gas to the substrate;
a nitriding gas supply part configured to supply a nitriding gas to the plasma formation region to generate a plasmarized nitriding gas and nitride the raw material adsorbed to the substrate using the plasmarized nitriding gas;
a controller configured to output a control signal such that a silicon-containing nitride film is formed by alternately and repeatedly supplying the raw material gas and supplying the plasmarized nitriding gas to the substrate; and
a storage part configured to store a first correspondence relationship between a stress of the silicon-containing nitride film and a parameter corresponding to a nitriding time in the plasma formation region,
wherein the controller is configured to output the control signal such that the plasmarized nitriding gas is supplied to the substrate during the nitriding time having a length that is based on a preset stress of the silicon-containing nitride film and the first correspondence relationship.

12. A film-forming apparatus, comprising:
a vacuum container including therein a mounting table in which a substrate is mounted;
a raw material gas supply part configured to supply a raw material gas containing silicon into the vacuum container to adsorb a raw material to the substrate;
a plasma formation region located in the vacuum container so as to plasmarize a gas supplied to the plasma formation region and supply a plasmarized gas to the substrate;
a nitriding gas supply part configured to supply a nitriding gas to the plasma formation region to generate a plasmarized nitriding gas and nitride the raw material adsorbed to the substrate, using the plasmarized nitriding gas;
a controller configured to output a control signal such that a silicon-containing nitride film is formed by alternately and repeatedly supplying the raw material gas and supplying the plasmarized nitriding gas to the substrate;
a hydrogen gas supply part configured to supply a hydrogen gas to the plasma formation region; and
a storage part configured to store a second correspondence relationship between a stress of the silicon-containing nitride film and a flow rate of the hydrogen gas supplied to the plasma formation region, and
wherein the controller is configured to output the control signal so that the hydrogen gas is supplied to the plasma formation region at the flow rate that is based on a preset stress of the silicon-containing nitride film and the second correspondence relationship.

13. The apparatus of claim 11, wherein the storage part is further configured to store the first correspondence relationship and a second correspondence relationship between the stress of the silicon-containing nitride film and a flow rate of a hydrogen gas supplied to the plasma formation region, and
wherein the controller is configured to output the control signal so that the plasmarized nitriding gas is supplied to the substrate during the nitriding time having the length that is based on the preset stress of the silicon-containing nitride film, and the hydrogen gas is supplied to the plasma formation region at the flow rate that is based on the preset stress of the silicon-containing nitride film.

14. The apparatus of claim 12, wherein the storage part is further configured to store a first correspondence relationship between the stress of the silicon-containing nitride film and a parameter corresponding to a nitriding time in the plasma formation region, and the second correspondence relationship, and
wherein the controller is configured to output the control signal so that the plasmarized nitriding gas is supplied to the substrate during the nitriding time having a length that is based on the preset stress of the silicon-containing nitride film, and the hydrogen gas is supplied to the plasma formation region at the flow rate that is based on the preset stress of the silicon-containing nitride film.
